(19) United States
(12) Patent Application Publication
(10) Pub. No.: US 2025/0125267 A1
(43) Pub. Date: Apr. 17, 2025

(54) SEMICONDUCTOR HAVING A FUNCTIONAL PROTECTION STRUCTURE AND METHOD OF MANUFACTURE

(71) Applicant: The Charles Stark Draper Laboratory, Inc., Cambridge, MA (US)

(72) Inventors: Richard MORRISON, Cambridge, MA (US); William A. ROY, Cambridge, MA (US); Kurt WIGHT, Cambridge, MA (US); Tirunelveli S. SRIRAM, Cambridge, MA (US)

(73) Assignee: The Charles Stark Draper Laboratory, Inc., Cambridge, MA (US)

(21) Appl. No.: 18/806,904

(22) Filed: Aug. 16, 2024

Related U.S. Application Data
(60) Provisional application No. 63/590,815, filed on Oct. 17, 2023.

(51) Int. Cl. H01L 23/532; H01L 21/02; H01L 21/3065; H01L 21/683; H01L 21/762; H01L 23/528

(52) U.S. Cl. CPC H01L 23/5329; H01L 21/02164; H01L 21/3065; H01L 21/6835; H01L 21/76224; H01L 23/5283; H01L 2221/68331

(57) ABSTRACT

Semiconductor device including semiconductor substrate having frontside and backside, at least one semiconductor die fabricated in frontside, wherein each of at least one semiconductor die comprises at least one semiconductor feature, wherein each at least one semiconductor die has a tensile strength, and wherein semiconductor substrate comprises at least one etching in backside thereof under at least one semiconductor feature of each at least one semiconductor die to reduce tensile strength of each at least one semiconductor die, first insulating material deposited on backside and partially in at least one etching, conductive material deposited on first insulating material and partially in at least one etching, wherein conductive material does not interfere with functionality of at least one semiconductor feature, second insulating material deposited on conductive material and partially in at least one etching, wherein second insulating material prevents migration of conductive material, and cap material attached to second insulating material.

### CROSS-REFERENCE TO RELATED APPLICATIONS

This application claims priority to U.S. Provisional Application Ser. No. 63/590,815, filed on Oct. 17, 2023, the content of which is hereby incorporated by reference in its entirety.

### STATEMENT REGARDING FEDERALLY SPONSORED RESEARCH

The inventions claimed herein were made with government support under contract number W9124P-19-9-0001. The government has certain rights in the inventions.

### FIELD OF DISCLOSURE

The present disclosure relates generally to semiconductor devices and, in particular, to structures and techniques for providing protection structures in semiconductor devices.

### BACKGROUND

In present day foundry processes, active circuit functionality is achieved at depths of approximately 1000 nanometers (nm) or less in a semiconductor substrate, where much of the semiconductor substrate provides structural rigidity rather than electrical functionality.

### SUMMARY

In accordance with the concepts described herein, described here are exemplary devices and structures directed toward a semiconductor die having a tuned protection feature on a semiconductor substrate and tuned protection feature in various configurations. The tuned protection feature may be etched on a backside of the semiconductor substrate in various shapes.

According to one aspect, a semiconductor device may include a semiconductor substrate having a frontside and a backside and at least one semiconductor die fabricated in the frontside of the semiconductor substrate. Each of the at least one semiconductor die may comprise at least one semiconductor feature. Each of the at least one semiconductor die may have a tensile strength. At least one protection feature may be provided in the backside of the semiconductor substrate under at least one semiconductor feature of at least one semiconductor die. The at least one protection feature may be configured to reduce the tensile strength of the at least one semiconductor die. A first insulating material may be deposited on the backside of the semiconductor substrate and partially in the at least one protection feature. A conductive material may be deposited on the first insulating material and partially in the at least one protection feature. The conductive material may not interfere with functionality of the at least one semiconductor feature and the first insulating material may prevent migration of the conductive material. A second insulating material may be deposited on the conductive material and partially in the at least one protection feature. A cap material may be attached to the second insulating material.

The semiconductor device may include, alone or in combination, one or more of the following features. A handle wafer may be attached to the semiconductor substrate. The handle wafer may be configured to enable thinning of the semiconductor substrate to within a range of 25 um to 200 um prior to forming a protection feature in the backside of the semiconductor substrate. An interposer may be attached to the frontside of the semiconductor substrate. The semiconductor substrate may comprise a silicon substrate having a diameter in a range of about 100 millimeters (mm) to about 300 mm and a thickness in a range of about 500 micrometers (um) to about 1000 um. The semiconductor substrate and the cap material may be one of a complementary metal oxide semiconductor (CMOS) silicon substrate, an N-channel metal oxide semiconductor silicon substrate, a P-channel metal oxide semiconductor silicon substrate, a Group Ill-V substrate, a bipolar junction substrate, and a high electron mobility substrate. The at least one semiconductor feature may comprise a quantum well, a deposition, a diffusion, a conductive layer, a resistive layer, a capacitance layer, an electrical component, an electrical circuit, and a memory cell. The electrical component may comprise a transistor, a resistor, a capacitor, and an inductor The at least one protection feature may be provided in the backside of the semiconductor substrate has a portion thereof disposed to within about 3 um of the at least one semiconductor feature. The first insulating material and the second insulating material may comprise one of Silicon Dioxide (SiO₂) and oxynitride (NₓOₓ). The first insulating material may comprise a thickness of about 100 nm, and the second insulating material may comprise a thickness of about 1.5 um. The conductive material may comprise a metal including Aluminum, Titanium, Platinum, and any combination thereof. The metal may not create a bandgap trap. The protective feature may be provided having a shape corresponding to one or a combination of: a circle, a square, a diamond, and a checkerboard pattern in any combination.

According to another aspect, a method of fabricating a semiconductor device may include providing a semiconductor substrate having a frontside and a backside and fabricating at least one semiconductor die in the frontside of the semiconductor substrate. Each of the at least one semiconductor die may comprise at least one semiconductor feature. Each of the at least one semiconductor die may have a tensile strength. At least one protection feature may be provided in the backside of the semiconductor substrate under at least one semiconductor feature of at least one semiconductor die. The at least one protection feature may be configured to reduce the tensile strength of the at least one semiconductor die. A first insulating material may be deposited on the backside of the semiconductor substrate and partially in the at least one protection feature. A conductive material may be deposited on the first insulating material and partially in the at least one protection feature. The conductive material may not interfere with functionality of the at least one semiconductor feature and the first insulating material may prevent migration of the conductive material. A second insulating material may be deposited on the conductive material and partially in the at least one protection feature. A cap material may be attached to the second insulating material.

The method may include, alone or in combination, one or more of the following features. Forming the at least one backside semiconductor feature may comprise etching at least one semiconductor feature in the backside of the semiconductor substrate. An interposer may be attached to the frontside of the semiconductor substrate. The semiconductor substrate may comprise a silicon substrate having a diameter in a range of about 100 millimeters (mm) to about 300 mm and a thickness in a range of about 500 micrometers (um) to about 1000 um. The semiconductor substrate and the cap material may be one of a complementary metal oxide semiconductor (CMOS) silicon substrate, an N-channel metal oxide semiconductor silicon substrate, a P-channel metal oxide semiconductor silicon substrate, a Group III-V substrate, a bipolar junction substrate, and a high electron mobility substrate. The semiconductor substrate may be thinned to within a range of about 25 um to about 200 um prior to forming the at least one backside semiconductor feature to reduce the tensile strength of the at least one semiconductor die. Etching the at least one backside semiconductor feature may comprise etching at least one of the at least one backside semiconductor features to within about 3 um of the at least one frontside semiconductor feature. The first insulating material and the second insulating material may comprise one of silicon dioxide (SiO₂) and oxynitride (NₓOₓ). The first insulating material may comprise a thickness of about 100 nm, and wherein the second insulating material comprises a thickness of about 1.5 μm. The conductive material may comprise a metal comprising aluminum, titanium, platinum, and any combination thereof. Forming the at least one semiconductor feature in the backside of the semiconductor substrate may comprise etching at least one shape into the backside of the semiconductor substrate. The at least one shape may comprise a circle, a square, a diamond, and a checkerboard pattern in any combination. The circle, the square, and the diamond each may comprise a diameter of about 50 um. The checkerboard may comprise a plurality of traces. Each of the plurality of traces comprise a width of about 150 um.

### BRIEF DESCRIPTION OF THE DRAWINGS

The manner and process of making and using the disclosed embodiments may be appreciated by reference to the figures of the accompanying drawings. It should be appreciated that the components and structures illustrated in the figures are not necessarily to scale, emphasis instead being placed upon illustrating the principles of the concepts described herein. Like reference numerals designate corresponding parts throughout the different views. For purposes of clarity, not every component may be labeled in every drawing. Furthermore, embodiments are illustrated by way of example and not limitation in the figures, in which:

FIGS. 1A-L includes a series of panels illustrating a series of cross-sectional views of an exemplary semiconductor device and process for forming a functional protection structure (also referred to herein as a protection feature) on the semiconductor device;

FIG. 2A is a perspective view of semiconductor devices having a protection feature;

FIG. 2B is a perspective view of semiconductor devices having a protection feature;

FIG. 2C is an enlarged view of a portion of FIG. 2B;

FIG. 2D is a perspective view of semiconductor devices having a protection feature;

FIG. 2E is a perspective view of semiconductor devices having a protection feature;

FIG. 2F is an enlarged view of a portion of FIG. 2E;

FIG. 2G is a top view of a semiconductor device having a protection feature;

FIG. 3 is a diagram illustrating exemplary shapes of a protection structure; and

FIG. 4 is a flowchart of an exemplary method for fabricating a semiconductor die having a protection feature.

### DETAILED DESCRIPTION

Aspects and embodiments disclosed herein are not limited in application to the details of construction and the arrangement of components set forth in the following description or illustrated in the drawings. Aspects and embodiments disclosed herein are capable of being practiced or of being carried out in various ways. Also, the phraseology and terminology used herein is for the purpose of description and should not be regarded as limiting. The use of “including,” “comprising,” “having,” “containing,” “involving,” and variations thereof herein is meant to encompass the items listed thereafter and equivalents thereof as well as additional items.

Aspects and embodiments disclosed herein include providing a functional protection structure in an integrated circuit (IC) or a semiconductor die containing semiconductor devices where the protection feature is configured to cause the semiconductor die to fracture, deform, distort (or generally change) in response to, or under influence of, an external force (i.e., a force externally applied to the IC or semiconductor die). Such changes in the IC or semiconductor die (regardless of the type of change) resultant from the protection structure may degrade electrical performance (i.e., the functional performance) of the semiconductor die or one or more devices on the die.

According to one aspect, the semiconductor die may be fabricated on a semiconductor substrate or wafer. In an exemplary embodiment, individual semiconductor die may be spaced about 35 micrometers (m) or more from one another. Further aspects and embodiments disclosed herein are directed toward methods for fabricating one or more protection features on a semiconductor die.

Still further aspects and embodiments disclosed herein include “tuning” a protection feature (i.e., selecting structural/physical characteristics of a protection feature).

Still further aspects and embodiments disclosed herein are directed toward methods for fabricating a functional protection structure in a semiconductor die containing semiconductor devices, where the protection feature is configured to cause the semiconductor die to fracture or deform under an influence of an external force in a manner that degrades electrical performance.

In accordance with the concepts described here, in contrast to known structures and techniques, exemplary aspects and embodiments disclosed herein may not require a thick semiconductor substrate to provide mechanical strength to a semiconductor die. For example providing a semiconductor die disclosed herein with thicknesses of about 10 μm or less in at least one portion of the semiconductor die may reduce the tensile strength of the semiconductor die to be reduced and, therefore may make the semiconductor die prone to mechanical and/or electrical failure if mishandled, interfered with, modified or otherwise intentionally compromised. Semiconductor die disclosed herein may thus be less tolerant of an attempt to intentionally compromise the semiconductor. Consequently, intentionally compromising a semiconductor die having one or more functional protection features in accordance with the concepts described herein may be detected in instances in which a conventional semiconductor die having a thicker and uniformly thick substrate would not indicate that it was interfered with, modified or otherwise intentionally compromised.

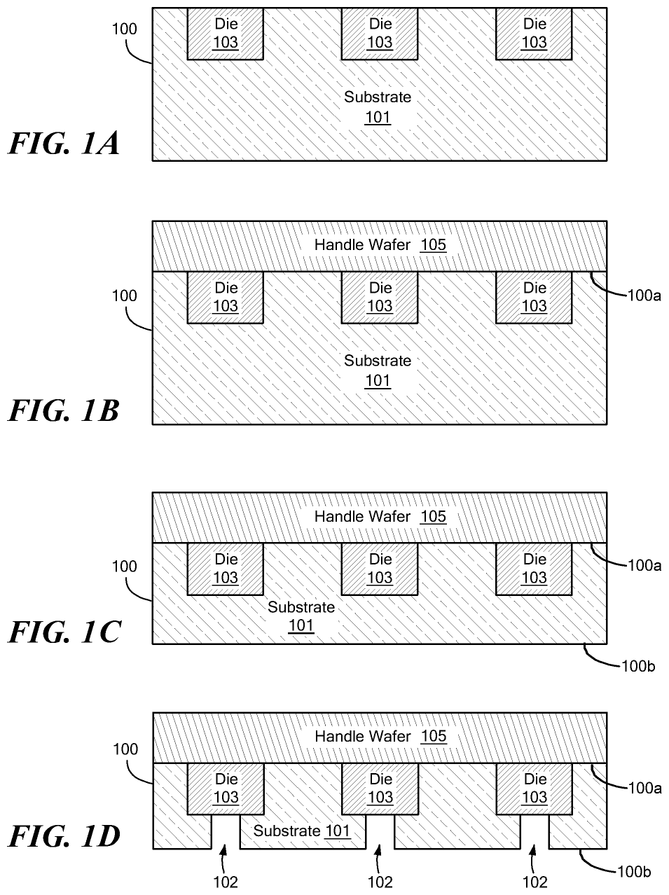

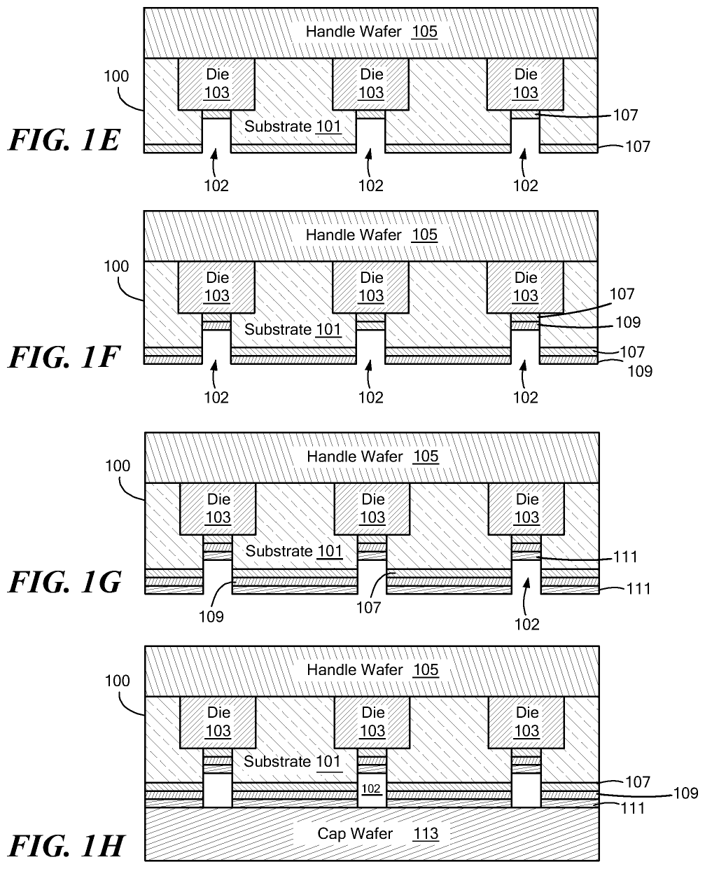

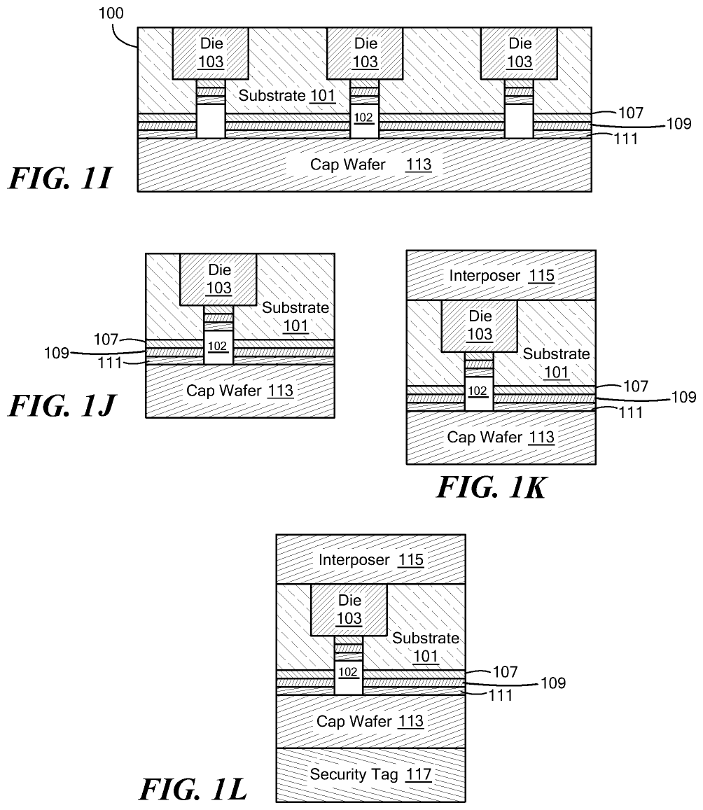

Referring now to FIGS. 1A-L, an exemplary semiconductor device 100 is illustrated having at least one tuned protection feature according to the concepts described herein. It should be appreciated that for ease of understanding, structures illustrated in FIGS. 1A-L are not to scale. Furthermore, and FIGS. 1A-L are all shown in one orientation, whereas any individual structure in FIGS. 1A-L may be in a different orientation (e.g., rotated 180 degrees) during a processing or fabrication step to achieve the result illustrated in the structure.

In an exemplary embodiment, the semiconductor substrate 101 may include a metal oxide semiconductor (MOS) substrate (e.g., n-channel MOS (NMOS), p-channel MOS (PMOS), or complementary MOS (CMOS), a Group III-V semiconductor (e.g., Gallium Nitride (GaN), Indium Nitride (InN), Gallium Arsenide (GaAs)), a bipolar junction (BJT) substrate, a high electron mobility (HEMT) substrate, Silicon Carbide substrate (SiC) and so on. For example, the semiconductor substrate 101 may be a silicon substrate about 100 millimeter (mm) to 300 mm in diameter and about 300 μm to 1000 μm thick.

Semiconductor device 100 may include the semiconductor substrate 101, a semiconductor die 103, a handle wafer 105 (FIG. 1B), a first insulating material 107 (FIG. 1E), a conductive material 109 (FIG. 1F), a second insulating material 111 (FIG. 1G), a cap wafer 113 (FIG. 1H), an interposer 115 (FIG. 1K), and/or a security tag 117 (FIG. 1L).

As illustrated in FIG. 1A, the semiconductor die 103 may be fabricated into the semiconductor substrate 101. In FIG. 1B, a handle wafer 105 may be attached to a first surface (also referred to as a front side) 100a of the semiconductor substrate 101, where the semiconductor die 103 are formed. The handle wafer 105 may include a material compatible with the semiconductor substrate 101 (e.g., if the semiconductor substrate 101 is silicon, then the handle wafer 105 may comprise silicon, glass, etc.). The handle wafer 105 may be attached to the semiconductor substrate 101 with any adhesive (not shown) appropriate for temporarily attaching the handle wafer 105 to the semiconductor substrate 101.

As shown in FIG. 1C, the semiconductor substrate 101 may be thinned from a second surface 100b (also referred to as a backside) of the semiconductor substrate 101 (i.e., on an opposite surface from where the semiconductor die 103 are fabricated). For example, the semiconductor substrate 101 may be thinned by backside grinding (BSG) followed by chemical mechanical polishing (CMP). For example, if the silicon substrate is about 700 μm thick then the semiconductor substrate 101 may be thinned to within a range from about 25 μm to about 200 μm. At least one protection feature is provided in the backside of the semiconductor substrate 101 under at least one portion of one or more (and in some embodiments each) of the semiconductor die 103. In embodiments, at least one protection feature may be provided by etching. In embodiments, at least one protection feature 102 (FIG. 1D) is provided (e.g., etched or otherwise provided) into a surface (e.g. a backside) of the semiconductor substrate 101 under at least one portion of each of the semiconductor die 103. In the case where semiconductor substrate 101 is silicon and an etching technique is used to provide the protection feature, then a deep reactive ion etch (DRIE) or a reactive ion etch (RIE) may be used to etch at least one protection feature into the semiconductor substrate 101. In embodiments, the backside of the semiconductor substrate 101 may be etched or otherwise formed to within about 3 μm of at least one semiconductor feature in the semiconductor die 103). In embodiments, an etched surface of a protection feature may be provided having a roughness in the range of about 20 nanometers (nm) to about 2000 nm, where the roughness contributes to a stress level in the semiconductor substrate 101. According to one aspect, the at least one semiconductor feature in the semiconductor die 103 may comprise a quantum well, a deposition, a diffusion, a conductive layer, a resistive layer, a capacitive layer, an electrical component (e.g., a transistor, a resistor, a capacitor, an inductor, etc.), an electrical circuit, at least one memory cell, and the like.

As illustrated in FIG. 1E, a first insulating material 107 may be deposited on the backside of the semiconductor substrate 101, where the at least one protection feature is less than completely filled (i.e., is partially filled) with the first insulating material 107. In embodiments (e.g., when the semiconductor substrate 101 is silicon) the first insulating material 107 may comprise silicon dioxide (SiO₂) or an oxynitride (NₓO_{y}). Other insulating materials may of course, be used when the semiconductor substrate 101 is a different material. After reading the description provided herein, one of ordinary skill in the art will understand how to select particular insulating materials for use in particular applications.

In an exemplary embodiment, the first insulating material 107 may be in the range of about 50 nm to about 2000 nm thick, which not only provides an insulation layer but also adds strength to effect stress in the semiconductor substrate 101. The first insulating material 107 may be deposited over a surface (e.g., a backside surface) of thinned substrate 101 using any suitable technique. In embodiments, the first insulating material 107 may be deposited over a surface of substrate 101 using a Chemical Vapor Deposition (CVD) technique such as a Plasma-enhanced Chemical Vapor Deposition (PECVD).

As shown in FIG. 1F, a conductive material 109 may be deposited on or otherwise disposed over the first insulating material 107, where the at least one protection feature 102 is less than completely filled (i.e., is partially filled) with the conductive material 109. Furthermore, conductive material 109 is selected and deposited or otherwise disposed in a manner such that conductive material 109 does not interfere with the functionality of the semiconductor die 103. In embodiments, conductive material 109 may be aluminum, titanium, platinum, or any combination thereof, etc. Such materials may be preferred when the protection feature is etched near a MOS transistor. In embodiments, conductive alloys may be used. It should be appreciated that other conductive materials may be used. After reading the disclosure provided herein, one of ordinary skill in the art will appreciate how to select a conductive material which is compatible with the material of the semiconductor substrate 101 and/or compatible with a semiconductor feature used in a particular application. In an exemplary embodiment, the conductive material 109 may be within a range from about 30 nm to about 1000 nm thick. A minimum thickness may be needed to achieve desired photonic behaviors and a maximum thickness may depend on an amount of stress and an amount of mechanical strength induced in the semiconductor substrate 101.

Materials such as copper (Cu) and gold (Au) may interfere with the functionality of the semiconductor die 103 (e.g., a band gap trap) and thus it may be desirable to avoid such conductive materials.

The first insulating material 107 may prevent migration of the conductive material 109 (e.g., metal migration if a metal is used as the conductive material 109).

As shown in FIG. 1G, a second insulating material 111 may be deposited on or otherwise disposed over conductive material 109, where the at least one protection feature is less than completely filled (i.e., is partially filled) with the second insulating material 111, and where the second insulating material 111 is used to cap the metallic layer and provide a surface for a cap wafer to adhere to. In embodiments, the second insulating material 111 may comprise silicon dioxide (SiO₂) and/or one or more other oxides (e.g., NₓO_{y}) when the semiconductor substrate 101 is silicon but may be a different material when the semiconductor substrate 101 is a different material. After reading the disclosure provided herein, one of ordinary skill in the art will appreciate how to select a second insulating material which is compatible with other materials being used and which meets the needs of the particular application. In an exemplary embodiment using Zibond®, the second insulating material 111 may be about 1.5 μm thick. Other bonding techniques may, of course, also be used and such bonding techniques may require that insulating material 111 have a different thickness. After reading the description provided herein, one of ordinary skill in the art will understand how to select layer thickness for use with particular bonding or other attachment techniques.

As shown in FIG. 1H, cap wafer 113 may be attached to the second insulating material 111. As illustrated in FIG. 1I, the handle wafer 105 may be removed after the cap wafer 113 is attached. The cap wafer 113 may be silicon if the semiconductor substrate 101 is silicon or a Group III-V material if the semiconductor substrate 101 is a Group III-V material. In embodiments, cap wafer 113 may be attached to the second insulating material 111 using the ZiBond® technique. Other techniques may also be used. In an exemplary embodiment, the cap wafer 113 may be about 625 μm thick, which may cause the result to be approximately equal to an initial thickness of the semiconductor substrate 101 (e.g., if the semiconductor substrate 101 has an initial thickness of about 725 μm and is thinned to about 100 μm then the cap wafer 113 may have a thickness of about 625 μm to result in a total thickness approximately equally to the initial thickness of the semiconductor substrate 101).

As illustrated in FIG. 1J, the functional semiconductor die 103 may be removed from the semiconductor substrate 101, where the semiconductor die 103 includes a portion of the semiconductor substrate 101, at least one protection feature, a portion of the first insulating material 107, a portion of the conductive material 109, a portion of the second insulating material 111, and a portion of the cap wafer 113.

As illustrated in FIG. 1K, an interposer 115 may be attached to a front side of a functional semiconductor die 103 removed from the semiconductor substrate 101. As shown in FIG. 1L, a security tag 117 may be attached to the cap wafer 113. According to one aspect, the security tag 117 may have a thickness substantially equal to that of the cap wafer 113.

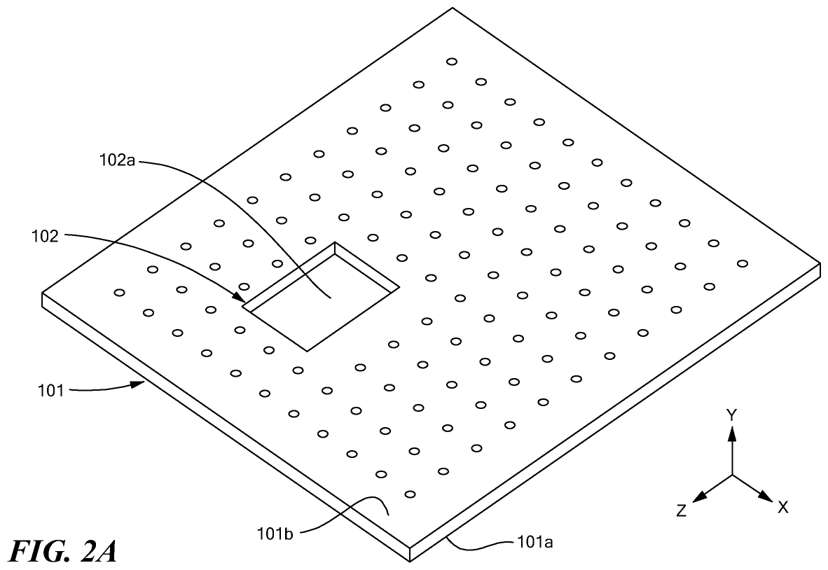

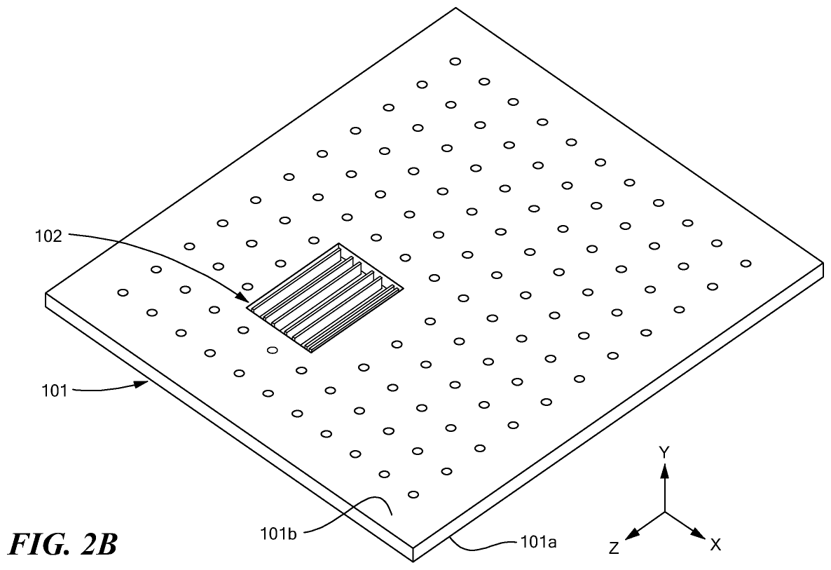

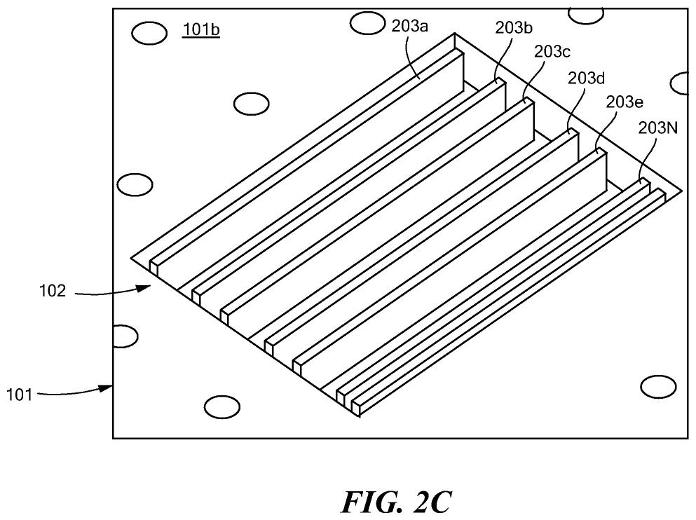

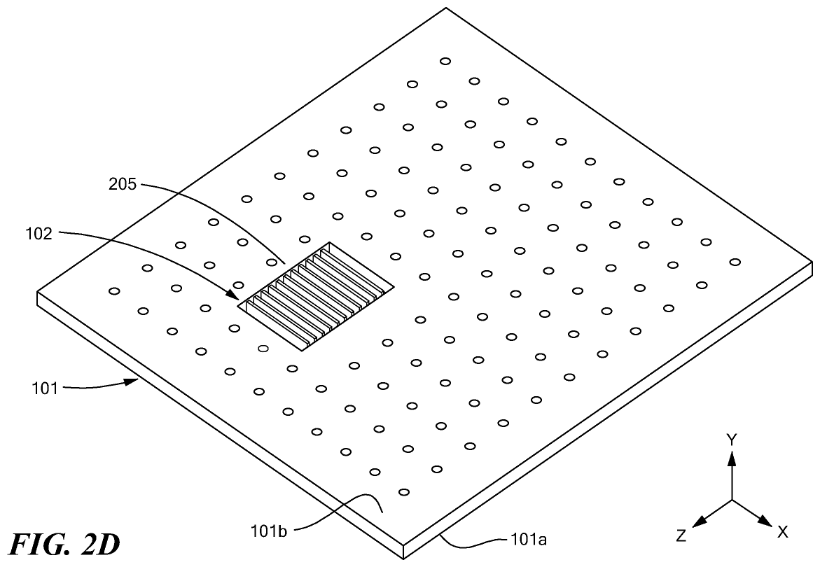

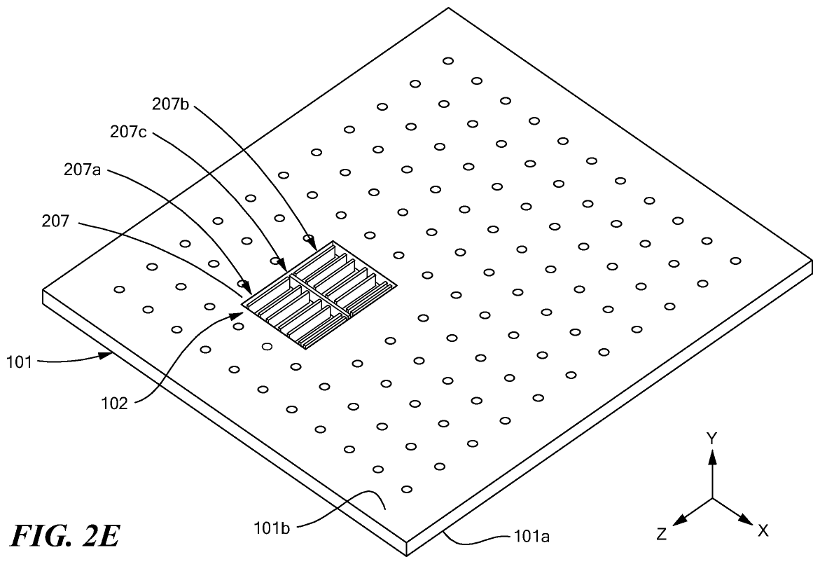

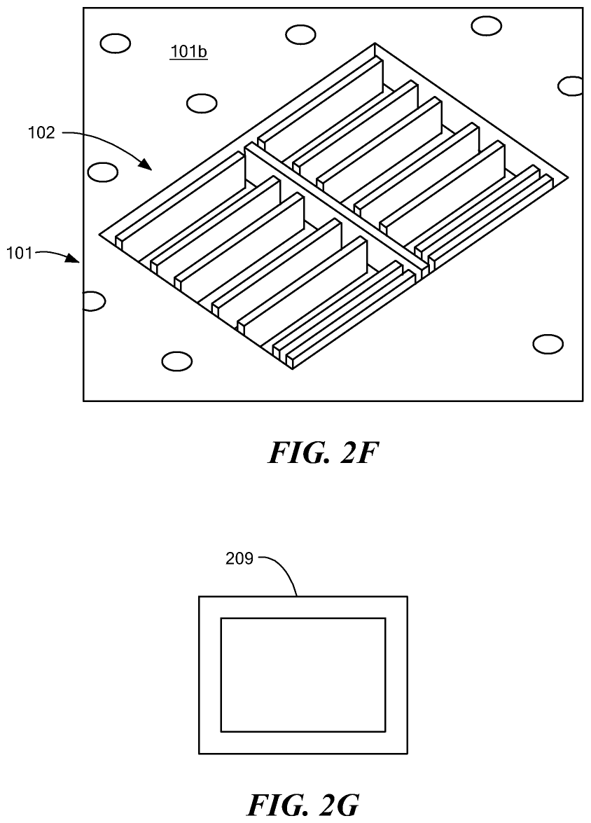

FIGS. 2A-2G are illustrations of exemplary protection features provided in accordance with the concepts described herein.

Referring now to FIG. 2A, an example semiconductor substrate 101 having first and second opposing surfaces 101a, 101b includes at least one protection feature 102 provided in at least one of the surfaces (here surface 101b). Semiconductor substrate 101 may comprise a semiconductor material. Semiconductor substrate 101 may comprise, for example, Group III-V materials or Group II-VI materials. In embodiments, the semiconductor material may comprise one, or combinations of, silicon, germanium, and gallium arsenide, as well as organic (SiC, etc.) semiconductors. Surface 101a may correspond to a frontside of semiconductor substrate 101 and surface 101b may correspond to a backside of semiconductor substrate 101. Thus, in this example, protection feature 102 is provided in a backside of the semiconductor substrate 101.

It is noted that semiconductor devices may be manufactured both as single discrete devices (e.g., including active and passive devices such as transistors and other electronic components, circuits and devices) and/or as an integrated circuit (IC or “chip”) which comprises two or more devices (including up to billions of devices) manufactured and interconnected (electrically) on a single semiconductor substrate or wafer. Thus, semiconductor substrate 101 may represent a structure comprising a single semiconductor device or billions of devices.

In the embodiment of FIG. 2A, the protection feature 102 may be provided as a recess region in the backside surface 101b of semiconductor substrate 101 with reference numeral 102a denoting a surface of the protection feature 102. The protection feature 102 is configured (i.e., provided having one or more structural characteristics) to cause a semiconductor die (e.g., semiconductor die 103 in FIG. 1) formed in the semiconductor substrate 101 to fracture or deform in response to, or under an influence of, a force (e.g., an external force applied to a device or a wafer) in a manner that degrades or destroys electrical performance. The one or more structural characteristics of the protection feature 102 which cause the semiconductor die to fracture or deform may be for example, one or more of (e.g., a combination of): a shape, a length, a width, a diameter, a depth, a pattern and/or a texture of one or more surfaces of the protection feature 102. In embodiments, the protection feature 102 may be provided under at least one semiconductor feature in at least one semiconductor die.

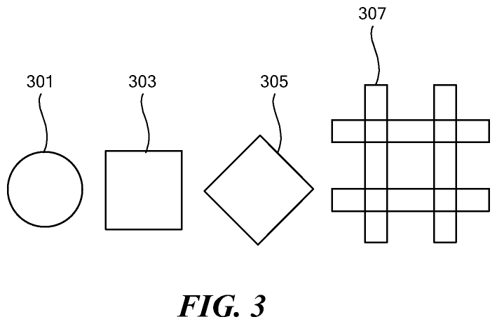

In the example embodiment of FIG. 2A the protection feature 102 is provided as an open recess region (e.g., a thinned region of a semiconductor substrate such as semiconductor substrate 101) having a substantially rectangular shape and a textured surface 102a (where a smooth surface or a roughened surface are both considered to be a form of a textured surface). Other shapes, may of course, also be used. Furthermore, the protection feature 102 may be provided having internal structures (or patterns), several example patterns of which are illustrated in FIG. 3 and FIGS. 2B-2G.

Referring now to FIGS. 2B, 2C, the protection feature 102 may include one or more structures (or ribs) with a plurality of ribs (here N ribs 203a-203N, referred to generally as ribs 203) being shown in FIG. 2C. Ribs 203 may be etched or otherwise provided in the backside 101b of the semiconductor substrate 101 under at least one semiconductor feature in at least one semiconductor die 103 (on frontside 101a). The plurality of ribs 203 may be spaced sufficiently close to each other to appear as one rectangular shape comprising a plurality of ribs 203 along an x-axis. In this example embodiment, ribs 203 may be provided having a substantially rectangular cross-sectional shape. In other embodiments, ribs 203 may be provided having a geometric cross-sectional shape including, but not limited to, regular or irregular geometric cross-sectional shapes, such as triangular, truncated triangular, square, oval shapes).

In FIG. 2D, the protection feature 102 may include a plurality of rectangular shapes 205 etched into the backside 101b of the semiconductor substrate 101 under at least one semiconductor feature in at least one semiconductor die 103 (on frontside 101a), where the plurality of rectangular shapes 205 are spaced sufficiently close to each other to appear as one rectangular shape comprising a plurality of ribs along a y-axis.

In FIGS. 2E, 2F the protection feature 102 may include a plurality of rectangular shapes 207 etched into the backside 101b of the semiconductor substrate 101 under at least one semiconductor feature in at least one semiconductor die 103 (on frontside 101a), where the plurality of rectangular shapes 207 are spaced sufficiently close to each other and arranged to appear as one rectangular shape comprising a plurality of ribs along a x-axis 207a, 207b and at least one rib along a z-axis 207c.

FIGS. 2A, 2B, 2C, and 2D illustrate at least one shape (e.g., a circle) etched into the backside 101b of the semiconductor substrate 101 in areas other than under at least one semiconductor feature in at least one semiconductor die 103 (on frontside 101a). However, the present disclosure is not limited to using a circular etching. Other shapes, as illustrated in FIG. 3 and described below in greater detail, may be used. In addition, FIG. 2A illustrates the use of one type of shape. However, the present disclosure is not limited to using one type of shape. Any suitable shape (e.g., the shapes illustrated in FIG. 3 and described below in greater detail) may be used in any combination and in any suitable number.

In FIG. 2G, the protection feature 102 comprises a rectangular trench 209 or moat etched into the backside 101b of the semiconductor substrate 101 under at least one semiconductor feature in at least one semiconductor die 103 (on frontside 101a).

FIG. 3 is an illustration of exemplary etching shapes according to the present disclosure. FIG. 3 illustrate various shapes (e.g., a circle 301, a square 303, a diamond 305, and a checkerboard 307) which may be etched into the backside 101b of the semiconductor substrate 101 in areas other than under at least one semiconductor feature in at least one semiconductor die 103 (on frontside 101a). Any suitable shape (e.g., the shapes illustrated in FIG. 3 and described herein) may be used in any combination and in any suitable number. The circle 301, square 303, and diamond 305 may each be approximately 50 μm in diameter, whereas traces that comprise the checkerboard 307 may be approximately 150 μm wide. However, the present disclosure is not limited to these sizes and any suitable diameters and widths may be used.

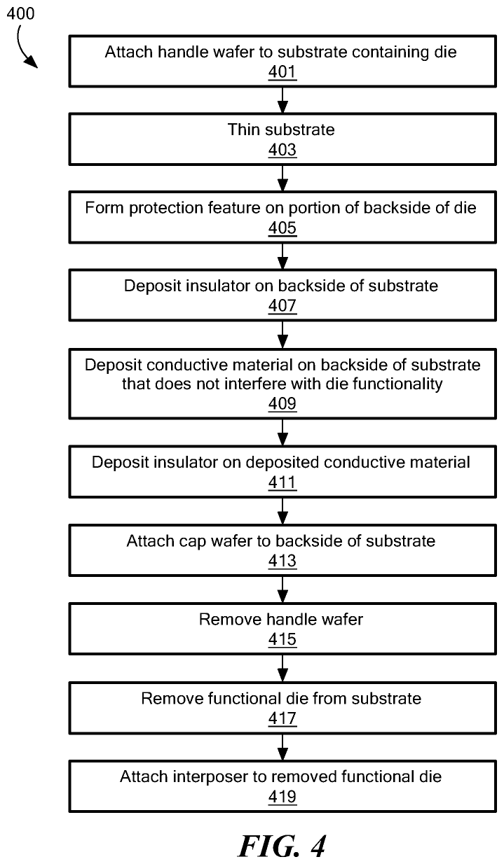

FIG. 4 is a flowchart of an exemplary method 400 for providing an integrated circuit (IC) or a semiconductor die with a protection feature. According to one aspect, the techniques described herein are post processing techniques of an IC after the IC is completed or a semiconductor die on a fabricated semiconductor substrate after it is completed. Process 401 of the method 400 may include attaching a handle wafer to a front side of the semiconductor substrate, where the semiconductor die are formed. Process 403 of the method 400 may include thinning the semiconductor substrate. This may be accomplished using a chemical or mechanical process. In embodiments, the semiconductor substrate may be thinned from the backside of the substrate. Process 405 of the method 400 may include forming (e.g., via an etching process) or otherwise providing at least one protection feature in at least one portion of a backside of a semiconductor die on the semiconductor substrate.

Process 407 of the method 400 may include depositing or otherwise providing a first insulating material on the backside of the semiconductor substrate, where the at least one protection feature is not completely filled with the first insulating material and preventing migration of the conductive material. Process 409 of the method 400 may include depositing or otherwise providing a conductive material on the first insulating material, where the at least one protection feature is not completely filled with the conductive material, and the conductive material does not interfere with the functionality of the semiconductor die. Process 411 of the method 400 may include depositing or otherwise providing a second insulating material on the conductive material, where the at least one protection feature is not completely filled with the second insulating material.

Process 413 of the method 400 may include disposing a cap wafer over the second insulating material. In embodiments, the cap wafer may, for example, be directly attached or coupled to the second insulating material. Process 415 of the method 400 may include removing the handle wafer. Process 417 of the method 400 may include removing functional semiconductor die from the semiconductor substrate. Process 419 of the method 400 may include attaching or coupling an interposer to a front side of a functional semiconductor die removed from the semiconductor substrate.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable sub combination. Other embodiments not specifically described herein are also within the scope of the following claims.

Various embodiments of the concepts, systems, devices, structures and techniques sought to be protected are described herein with reference to the related drawings. Alternative embodiments can be devised without departing from the scope of the concepts, systems, devices, structures and techniques described herein.

It is noted that various connections and positional relationships (e.g., over, below, adjacent, etc.) are set forth between elements in the above description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance, or illustration. Any embodiment or design described herein as “exemplary” is not necessarily to be construed as preferred or advantageous over other embodiments or designs. The terms “one or more” and “at least one” are understood to include any integer number greater than or equal to one, i.e., one, two, three, four, etc. The terms “a plurality” are understood to include any integer number greater than or equal to two, i.e., two, three, four, five, etc. The term “connection” can include an indirect “connection” and a direct “connection”.

References in the specification to “one embodiment, “an embodiment,” “an example embodiment,” etc., indicate that the embodiment described can include a particular feature, structure, or characteristic, but every embodiment can include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description herein, terms such as “upper,” “lower,” “right,” “left,” “vertical,” “horizontal, “top,” “bottom,” (to name but a few examples) and derivatives thereof shall relate to the described structures and methods, as oriented in the drawing figures. The terms “overlying,” “atop,” “on top, “positioned on” or “positioned atop” mean that a first element, such as a first structure, is present on a second element, such as a second structure, where intervening elements such as an interface structure can be present between the first element and the second element. The term “direct contact” means that a first element, such as a first structure, and a second element, such as a second structure, are connected without any intermediary elements. Such terms are sometimes referred to as directional or positional terms.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately” and “about” may be used to mean within +20% of a target value in some embodiments, within ±10% of a target value in some embodiments, within ±5% of a target value in some embodiments, and yet within ±2% of a target value in some embodiments. The terms “approximately” and “about” may include the target value. The term “substantially equal” may be used to refer to values that are within +20% of one another in some embodiments, within ±10% of one another in some embodiments, within ±5% of one another in some embodiments, and yet within ±2% of one another in some embodiments.

The term “substantially” may be used to refer to values that are within +20% of a comparative measure in some embodiments, within ±10% in some embodiments, within ±5% in some embodiments, and yet within ±2% in some embodiments. For example, a first direction that is “substantially” perpendicular to a second direction may refer to a first direction that is within ±20% of making a 90° angle with the second direction in some embodiments, within ±10% of making a 90° angle with the second direction in some embodiments, within ±5% of making a 90° angle with the second direction in some embodiments, and yet within ±2% of making a 90° angle with the second direction in some embodiments.

It is to be understood that the disclosed subject matter is not limited in its application to the details of construction and to the arrangements of the components set forth in the following description or illustrated in the drawings. The disclosed subject matter is capable of other embodiments and of being practiced and carried out in various ways.

Also, it is to be understood that the phraseology and terminology employed herein are for the purpose of description and should not be regarded as limiting. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

1. A semiconductor device, comprising:
a semiconductor substrate having a frontside and a backside;
at least one semiconductor die fabricated in the frontside of the semiconductor substrate, wherein each of the at least one semiconductor die comprises at least one semiconductor feature, wherein each of the at least one semiconductor die has a tensile strength; and
at least one protection feature provided in the backside of the semiconductor substrate under at least one semiconductor feature of at least one semiconductor die, the at least one protection feature configured to reduce the tensile strength of the at least one semiconductor die.

2. The semiconductor device of claim 1, comprising:
a first insulating material deposited on the backside of the semiconductor substrate and partially in the at least one protection feature;
a conductive material deposited on the first insulating material and partially in the at least one protection feature, wherein the conductive material does not interfere with functionality of the at least one semiconductor feature and the first insulating material prevents migration of the conductive material;
a second insulating material deposited on the conductive material and partially in the at least one protection feature; and
a cap material attached to the second insulating material.

3. The semiconductor device of claim 2, wherein the semiconductor substrate and the cap material are one of a complementary metal oxide semiconductor (CMOS) silicon substrate, an N-channel metal oxide semiconductor silicon substrate, a P-channel metal oxide semiconductor silicon substrate, a Group III-V substrate, a bipolar junction substrate, and a high electron mobility substrate.

4. The semiconductor device of claim 2, wherein the first insulating material and the second insulating material comprise one of Silicon Dioxide (SiO₂) and oxynitride (NₓOₓ), wherein the first insulating material comprises a thickness of about 100 nm, and wherein the second insulating material comprises a thickness of about 1.5 um.

5. The semiconductor device of claim 2, wherein the conductive material comprises a metal comprising Aluminum, Titanium, Platinum, and any combination thereof, wherein the metal does not create a bandgap trap.

6. The semiconductor device of claim 1, further comprising a handle wafer attached to the semiconductor substrate, the handle wafer configured to enable thinning of the semiconductor substrate to within a range of 25 um to 200 um prior to forming the at least one protection feature in the backside of the semiconductor substrate.

7. The semiconductor device of claim 1, further comprising an interposer attached to the frontside of the semiconductor substrate.

8. The semiconductor device of claim 1, wherein the semiconductor substrate comprises a silicon substrate having a diameter in a range of about 100 millimeters (mm) to about 300 mm and a thickness in a range of about 500 micrometers (um) to about 1000 um.

9. The semiconductor device of claim 1, wherein the at least one semiconductor feature comprises a quantum well, a deposition, a diffusion, a conductive layer, a resistive layer, a capacitance layer, an electrical component, an electrical circuit, and a memory cell, wherein the electrical component comprises a transistor, a resistor, a capacitor, and an inductor.

10. The semiconductor device of claim 1, wherein the at least one protection feature provided in the backside of the semiconductor substrate has a portion thereof disposed to within about 3 um of the at least one semiconductor feature.

11. The semiconductor device of claim 1, wherein the at least one protection feature is provided having a shape corresponding to one or a combination of: a circle, a square, a diamond, and a checkerboard pattern in any combination.

12. A method of fabricating a semiconductor device, comprising:
providing a semiconductor substrate having a frontside and a backside;
fabricating at least one semiconductor die in the frontside of the semiconductor substrate, wherein each of the at least one semiconductor die comprises at least one semiconductor feature, wherein each of the at least one semiconductor die has a tensile strength; and
forming in the backside of the semiconductor substrate at least one backside semiconductor feature under at least one semiconductor die to reduce the tensile strength of each of the at least one semiconductor die.

13. The method of claim 12 further comprising:
disposing a first insulating material on the backside of the semiconductor substrate and partially in the at least one etching;
disposing a conductive material on the first insulating material and partially in the at least one etching, wherein the conductive material does not interfere with functionality of the at least one semiconductor feature and the first insulating material prevents migration of the conductive material;
disposing a second insulating material deposited on the conductive material and partially in the at least one etching; and
attaching a cap material to the second insulating material.

14. The method of claim 13, wherein the semiconductor substrate and the cap material are one of a complementary metal oxide semiconductor (CMOS) silicon substrate, an N-channel metal oxide semiconductor silicon substrate, a P-channel metal oxide semiconductor silicon substrate, a Group III-V substrate, a bipolar junction substrate, and a high electron mobility substrate.

15. The method of claim 13, wherein the first insulating material and the second insulating material comprise one of silicon dioxide (SiO₂) and oxynitride (NₓOₓ), wherein the first insulating material comprises a thickness of about 100 nm, and wherein the second insulating material comprises a thickness of about 1.5 μm.

16. The method of claim 12, wherein forming the at least one backside semiconductor feature comprises etching at least one semiconductor feature in the backside of the semiconductor substrate.

17. The method of claim 16, wherein etching the at least one backside semiconductor feature comprises etching at least one of the at least one backside semiconductor features to within about 3 um of the at least one frontside semiconductor feature.

18. The method of claim 12, further comprising attaching an interposer to the frontside of the semiconductor substrate.

19. The method of claim 12, further comprising thinning the semiconductor substrate to within a range of about 25 um to about 200 um prior to forming the at least one backside semiconductor feature to reduce the tensile strength of the at least one semiconductor die.

20. The method of claim 12, wherein forming the at least one semiconductor feature in the backside of the semiconductor substrate comprises etching at least one shape into the backside of the semiconductor substrate, wherein the at least one shape comprises a circle, a square, a diamond, and a checkerboard pattern in any combination, wherein the circle, the square, and the diamond each comprise a diameter of about 50 um, and wherein the checkerboard pattern comprises a plurality of traces, wherein each of the plurality of traces comprising a width of about 150 um.
